(19) United States
(12) Patent Application Publication
(10) Pub. No.: US 2024/0410747 A1
(43) Pub. Date: Dec. 12, 2024

(54) METHOD FOR HIGH PRESSURE REGULATION AND CONTROL OF PHOTOELECTRIC DETECTION BASED ON BiOBr

(71) Applicant: Jilin University, Changchun City (CN)

(72) Inventors: Quanjun LI, Changchun City (CN); Lei Yue, Changchun City (CN); Ran Liu, Changchun City (CN); Bingbing Liu, Changchun City (CN)

(21) Appl. No.: 18/414,426

(22) Filed: Jan. 16, 2024

(30) Foreign Application Priority Data
Jun. 6, 2023 (CN) 202310664845X

(51) Int. Cl. G01J 1/42; H01L 31/032; H01L 31/18

(52) U.S. Cl. CPC G01J 1/429; H01L 31/032; H01L 31/18

(57) ABSTRACT

The present disclosure relates to a method for high pressure regulation and control of photoelectric detection based on BiOBr, and relates to the technical field of photoelectric detection. An exemplary method includes inserting an insulation layer into a pressure chamber of a diamond anvil cell and adding BiOBr, putting a pressure-calibrating substance on a culet of the diamond anvil cell; pressurizing the pressure chamber by rotating a press bolt on the diamond anvil cell; and conducting photoelectric detection using the pressurized BiOBr, where two platinum sheets are disposed on the BiOBr as an electrode. The present disclosure enhances the photo-response speed and photo-responsivity of photoelectric detection.

### CROSS REFERENCE TO RELATED APPLICATION

This patent application claims the benefit and priority of Chinese Patent Application No. 202310664845X, filed with the China National Intellectual Property Administration on Jun. 6, 2023, the disclosure of which is incorporated herein in its entirety by reference and by enclosure herewith (as an Appendix) as part of the present application.

### TECHNICAL FIELD

The present disclosure relates to the technical field of photoelectric detection, and in particular to, a method for high pressure regulation and control of photoelectric detection based on BiOBr.

### BACKGROUND

As a core part of the optoelectronics industry, photoelectric detectors have been widely used in many fields such as optoelectronic display, optical communications, spectral analysis, and security inspection. The next generation of photoelectric detectors is developed aimed at multidimensional ultra-sensitive optical information detection with a broadband, an ultra-small pixel and large-area arrays at room temperature. A single ultra-high performance index has been achieved on the basis of a lamellar semiconductor, but the overall performance of its photoelectric detector is not satisfactory. Response speed and responsivity are two key performance indexes of a photoelectric detector, while these two parameters are always mutually restrained and cannot be achieved at the same time. Therefore, how to improve the responsivity and response speed of a photoelectric detector simultaneously is still a great challenge.

### SUMMARY

An objective of the present disclosure is to provide a method for high pressure regulation and control of photoelectric detection based on BiOBr, thereby enhancing the response speed and photo-responsivity of photoelectric detection.

To achieve the above objective, the present invention provides the following technical solutions:
a method for high pressure regulation and control of photoelectric detection based on BiOBr includes:
inserting an insulation layer into a pressure chamber of a diamond anvil cell and adding BiOBr, disposing two platinum sheets on the BiOBr as an electrode, and placing a pressure-calibrating substance on a culet of the diamond anvil cell;
pressurizing the pressure chamber by rotating a press bolt on the diamond anvil cell; and
conducting photoelectric detection using the pressurized BiOBr.

Optionally, the diamond anvil cell has a culet diameter of 400 μm.

Optionally, the inserting an insulation layer into a pressure chamber of a diamond anvil cell specifically includes:
placing a T301 steel sheet into the pressure chamber and pre-pressing the T301 steel sheet by a thickness of 40 μm via the diamond anvil cell;
punching the pre-pressed T301 steel sheet using a laser boring device to obtain a sample chamber having a diameter of 300 μm; and
filling an insulation powder 6 in the sample chamber, and pre-pressing the sample chamber filled with the insulation powder such that the insulation powder is attached to the T301 steel sheet.

Optionally, the pressure-calibrating substance includes a ruby.

Optionally, a pressure is calibrated by a fluorescence peak of the ruby when the pressure chamber is pressurized by rotating a press bolt on the diamond anvil cell.

Optionally, the pressure chamber is pressurized by rotating a press bolt on the diamond anvil cell at pressure points of 1.0 GPa, 1.9 GPa, 2.5 GPa, 3.1 GPa, and 3.7 GPa.

Optionally, after pressurizing the pressure chamber by rotating a press bolt on the diamond anvil cell, the method further includes:
conducting an in situ high pressure photoresponse test on the BiOBr, specifically including:
connecting one end of a copper wire to the platinum electrode, and drawing the other end of the copper wire outside the diamond anvil cell and connecting to a Keithley 2461 source meter;
using the Keithley 2461 source meter as equipment for the in situ high pressure photoresponse test on the BiOBr, and using the Keithley 2461 source meter to apply a 10 V bias voltage to the BiOBr;
using a pulse laser with a frequency of 1 HZ as a light source to intermittently irradiate the BiOBr, where an irradiation time is 0.5 s, the same as an interval time; and
recording a current-time curve at each of the pressure points in a process of intermittent irradiation, determining whether a photo-responsivity and a photo-response speed of the BiOBr are enhanced according to the current-time curve, and determining a pressure applied for photoelectric detection of the BiOBr.

Optionally, the pulse laser irradiates the BiOBr at an optical power density of 0.3 mW/cm².

According to the specific embodiments provided herein, the present disclosure provides the following technical effects:

In the present disclosure, an insulation layer is inserted into a pressure chamber of a diamond anvil cell and a semiconductor BiOBr is placed into the pressure chamber; two platinum sheets serve as an electrode to contact with the semiconductor BiOBr, and then a pressure-calibrating substance is put on a culet of the diamond anvil cell. A press bolt is rotated to pressurize the pressure chamber, to improve the photoelectric response characteristic of BiOBr in the pressure chamber. The technique of high-pressure photoelectric experiments is applied in the method for improving the photoelectric response characteristic of the semiconductor BiOBr described above, which may effectively regulate the photoelectric/spectral responsivity and spectral response speed of the semiconductor BiOBr. The method of the present disclosure is simple and efficient without any dopant introduction and regulation of material dimension and thus, can be generalized to the enhancement of optoelectronic characteristics of more semiconductors after release of pressure.

### BRIEF DESCRIPTION OF THE DRAWINGS

To describe the technical solutions in embodiments of the present disclosure more clearly, the accompanying drawings of the embodiments are briefly described below. Notably, the accompanying drawings in the following description show only some embodiments of the present disclosure, and other drawings can be derived from these accompanying drawings by those of ordinary skill in the art without creative efforts.

FIG. 1 is a schematic flowchart showing a method for high pressure regulation and control of photoelectric detection based on BiOBr according to an embodiment of the present disclosure;

FIG. 2 is a schematic diagram showing that a diamond anvil cell provides a pressure to BiOBr according to an embodiment of the present disclosure;

FIG. 3 shows a current-time curve of BiOBr under each preset pressure according to an embodiment of the present disclosure;

FIG. 4 is a schematic diagram showing an absorption spectrum of BiOBr during pressurization according to an embodiment of the present disclosure; and

FIG. 5 is a schematic diagram showing changes in the band gap of BiOBr with pressure according to an embodiment of the present disclosure;

### REFERENCE NUMERALS

1—laser; 2—BiOBr; 3—platinum sheet; 4—T301 steel sheet, 5—Keithley 2461 source meter, and 6—insulation powder and/or pressure-calibrating substance.

### DETAILED DESCRIPTION OF THE EMBODIMENTS

The technical solutions of the embodiments of the present disclosure are clearly and completely described below with reference to the drawings. Further, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

An objective of the present disclosure is to provide a method for high pressure regulation and control of photoelectric detection based on BiOBr, thereby enhancing the photo-response speed and photo-responsivity of photoelectric detection.

To make the above objectives, features, and advantages of the present disclosure clearer and more comprehensible, the present disclosure will be further described in detail below with reference to the accompanying drawings and the specific examples.

### Embodiment 1

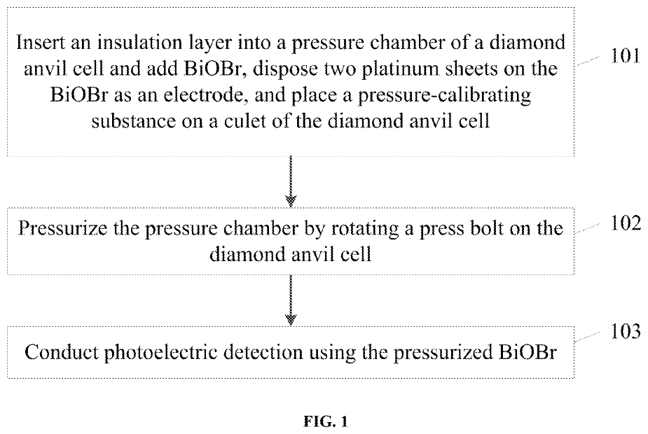

As shown in FIG. 1, the present disclosure discloses a method for high pressure regulation and control of photoelectric detection based on BiOBr, including the following steps.

Step 101: insert an insulation layer into a pressure chamber of a diamond anvil cell and add BiOBr; dispose two platinum sheets on the BiOBr as an electrode, and place a pressure-calibrating substance on a culet of the diamond anvil cell.

Step 102: pressurize the pressure chamber by rotating a press bolt on the diamond anvil cell.

Step 103: conduct photoelectric detection using the pressurized BiOBr.

The diamond anvil cell is used to provide each preset pressure for BiOBr.

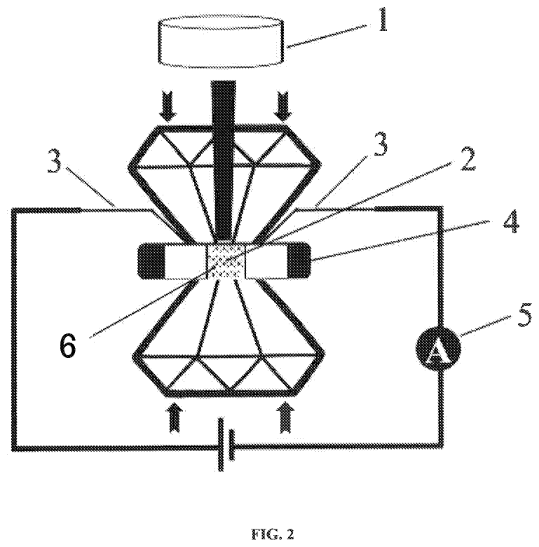

As shown in FIG. 2, the step of using the diamond anvil cell to provide each preset pressure for BiOBr 2 specifically includes: pressing in a metallic gasket (a T301 steel sheet 4) between an upper diamond and a lower diamond of the diamond anvil cell.

A circular hole having a preset diameter is drilled at the center of indentation of the metallic gasket as a sample chamber.

Electric insulation is conducted in the sample chamber, between the metallic gasket and the upper diamond, as well as between the metallic gasket and the lower diamond.

The BiOBr 2 and the pressure-calibrating substance are placed into the sample chamber; one end of the platinum sheet 3 contacts with the BiOBr 2, and the other end thereof is connected to the Keithley 2461 source meter 5 via wires; the Keithley 2461 source meter 5 is configured to provide a bias voltage for the BiOBr 2. The step specifically includes as follows: two pieces of enameled wires connected to BiOBr are drawn out, and connected to two probes of the Keithley 2461 source meter 5 after paint removal from the tail ends, then the source meter 5 applies a 10 V bias voltage to the semiconductor BiOBr. Because a current carrier is generated under light irradiation and requires voltage driving to achieve directional movement, and a bias voltage needs to be applied to most of photoelectric detectors.

A piece of ruby serves as the pressure-calibrating substance.

The upper diamond and the lower diamond are closed, and then the press bolt gets back to the original position.

The diamond anvil cell has a culet diameter of 400 μm, and the preset diameter is 180 μm. The metallic gasket is a T301 steel sheet having a thickness of 40 μm.

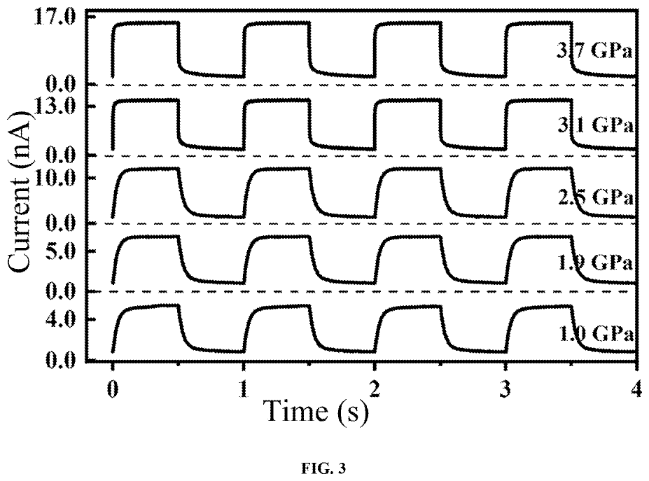

A pulse laser with a wavelength of 405 nm and a frequency of 1 Hz is used as a light source to provide illumination with a preset frequency for BiOBr; the laser irradiates the BiOBr at an optical power density of about 0.3 mW/cm²; and 5 cyclic current-time curves are recorded at each pressure point. The initial pressure point is 1.0 GPa; the pressurization gradient is controlled within 1.0 G Pa, the maximum pressure of the experiment is 3.7 GPa; that is, each pressure point ranges from 1.0 GPa to 3.7 GPa. As shown in FIG. 3, each pressure point in high pressure regulation and control includes 1.0 GPa, 1.9 GPa, 2.5 GPa, 3.1 GPa, and 3.7 GPa.

In this embodiment, the diamond anvil cell (DAC) having a culet diameter of 400 μm is used to pre-pressurize the T301 steel sheet as a gasket material by a thickness of about 40 μm, and a circular hole with a diameter of 180 is drilled by using a laser at the center of indentation of the T301 steel sheet as a sample chamber. A layer of boron nitride (c-BN) is inserted between the metallic gasket and the diamond to achieve electric insulation between the platinum electrode and the metallic gasket. One end of the two platinum sheets, as the electrode, contacts with the sample, and the other end partially contacts with the unenameled/unpainted portion of the 0.1 mm enameled wire. The probes of the Keithley 2461 source meter are connected to the enameled wire, and a bias voltage of 10 V is applied to record whether there is a current-time curve with/without 405 nm laser radiation. It begins to apply pressure to BiOBr from the initial pressure of 1.0 GPa, and whether there exists a current change with/without light radiation is recorded. When the pressure is applied to 3.7 GPa, as shown in FIG. 3, the photo-responsivity and photo-response speed are enhanced synchronously significantly.

The metallic gasket is coated to achieve electric insulation from the platinum electrode, which specifically includes: the sample chamber is fully filled with a c-BN powder, and then pre-pressed once again by 20 GPa such that the c-BN powder is attached to the metallic gasket (T301 steel sheet) closely, thereby achieving electric insulation between the platinum electrode and the metallic gasket. That is, a layer of c-BN is inserted between the metallic gasket and the diamond to achieve electric insulation between the platinum electrode and the metallic gasket. Afterwards, two platinum sheets are connected as an electrode, one end of the electrode contacts with the sample, and the other end partially contacts with the unenameled portion of the 0.1 mm enameled wire via a conductive silver adhesive.

In this embodiment, an anvil pressing device (the diamond anvil cell) composed of two symmetric diamonds with a culet diameter of 400 μm is used to produce high pressure, which may regulate the photo-responsivity and photo-response speed of BiOBr via the diamond anvil cell.

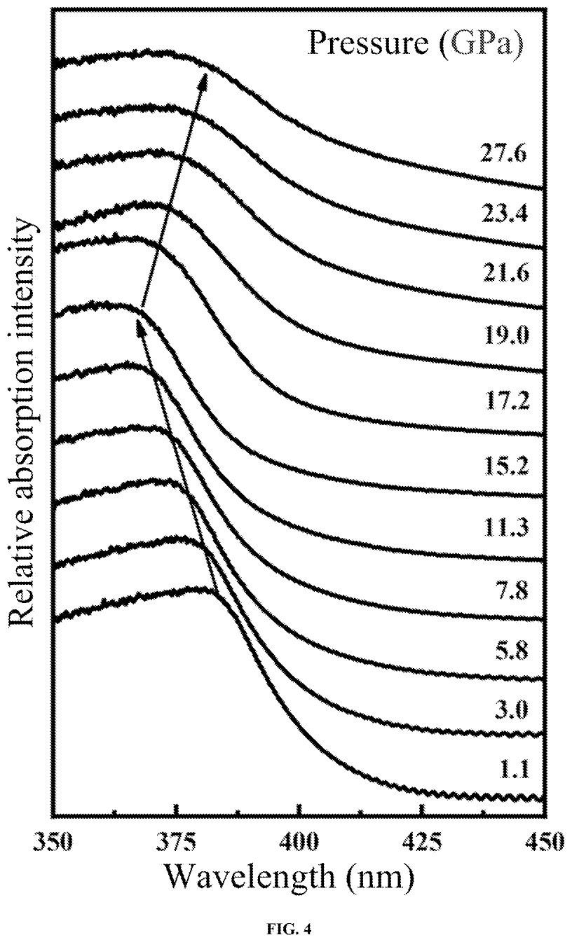

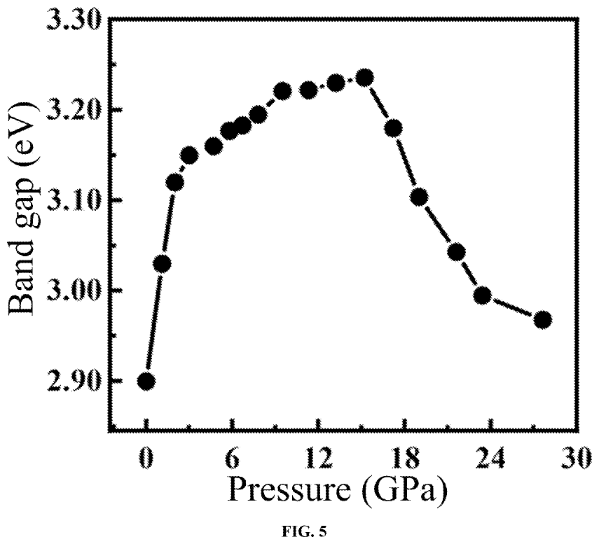

As shown in FIG. 3, the photo-responsivity and photo-response speed of BiOBr are enhanced simultaneously with the increase of pressure. Moreover, in situ high pressure of the band gap of a semiconductor iodine may be represented by a UV-visible spectrum (FIGS. 4 and 5), which validates that the band gap of BiOBr gradually increases with the increase of pressure prior to 15.2 GPa, but decreases when pressure continues to be applied. Preferably, the maximum pressure in the experiment is 3.7 GPa; the BiOBr sample has an optimal photo-responsivity and photo-response speed at a pressure of 3.7 GPa.

High pressure conditions are applied in the present disclosure, which may effectively regulate the separation and transmission of the current carrier of a semiconductor BiOBr, thereby regulating the photo-responsivity and photo-response speed. The method herein is simple and efficient without any dopant introduction and regulation of material dimension and thus, may be generalized to the regulation and control of more lamellar semiconductor materials in photo-responsivity and photoelectric response speed.

Each embodiment of the present specification is described in a progressive manner, each embodiment focuses on the difference from other embodiments, and the same and similar parts between the embodiments may refer to each other.

Specific examples are used herein to explain the principles and embodiments of the present disclosure. The foregoing description of the embodiments is merely intended to help understand the method of the present disclosure and its core ideas; besides, various modifications may be made by those of ordinary skill in the art to specific embodiments and the scope of application in accordance with the ideas of the present disclosure. In conclusion, the content of the present specification shall not be construed as limitations to the present disclosure.

1. A method for high pressure regulation and control of photoelectric detection based on BiOBr, comprising:
inserting an insulation layer into a pressure chamber of a diamond anvil cell and adding BiOBr, disposing two platinum sheets on the BiOBr as an electrode, and placing a pressure-calibrating substance on a culet of the diamond anvil cell;
pressurizing the pressure chamber by rotating a press bolt on the diamond anvil cell; and
conducting photoelectric detection using the pressurized BiOBr.

2. The method of claim 1, wherein the diamond anvil cell has a culet diameter of 400 μm.

3. The method of claim 1, wherein the inserting an insulation layer into a pressure chamber of a diamond anvil cell comprises:
placing a T301 steel sheet into the pressure chamber and pre-pressing the T301 steel sheet by a thickness of 40 μm via the diamond anvil cell;
punching the pre-pressed T301 steel sheet using a laser boring device to obtain a sample chamber having a diameter of 300 μm; and
filling an insulation powder in the sample chamber, and pre-pressing the sample chamber filled with the insulation powder such that the insulation powder is attached to the T301 steel sheet.

4. The method of claim 1, wherein the pressure-calibrating substance comprises ruby.

5. The method of claim 4, wherein a pressure is calibrated by a fluorescence peak of the ruby when the pressure chamber is pressurized by rotating a press bolt on the diamond anvil cell.

6. The method of claim 1, wherein the pressure chamber is pressurized by rotating a press bolt on the diamond anvil cell at pressure points of 1.0 GPa, 1.9 GPa, 2.5 GPa, 3.1 GPa, and 3.7 GPa.

7. The method of claim 6, after the pressurizing the pressure chamber by rotating a press bolt on the diamond anvil cell, further comprising:
conducting an in situ high pressure photoresponse test on the BiOBr, specifically comprising:
connecting one end of a copper wire to the platinum electrode, and drawing the other end of the copper wire outside the diamond anvil cell and connecting to a Keithley 2461 source meter;
using the Keithley 2461 source meter as equipment for the in situ high pressure photoresponse test on the BiOBr, and using the Keithley 2461 source meter to apply a 10 V bias voltage to the BiOBr;
using a pulse laser with a frequency of 1 Hz as a light source to intermittently irradiate the BiOBr, wherein an irradiation time is 0.5 s, the same as an interval time; and
recording a current-time curve at each of the pressure points in a process of intermittent irradiation, determining whether a photo-responsivity and a photo-response speed of the BiOBr are enhanced according to the current-time curve, and determining a pressure applied for photoelectric detection of the BiOBr.

8. The method of claim 7, wherein the pulse laser irradiates the BiOBr at an optical power density of 0.3 mW/cm².

9. A system, in which the method described in claim 1 is performed, the system comprising:
the diamond anvil cell including:
the pressure chamber including the insulation layer, the BiOBr, the two platinum sheets, and the pressure-calibrating substance on the culet of the diamond anvil cell; and
the press bolt;
wherein the diamond anvil cell has a culet diameter of 400 μm.

10. The system of claim 9, wherein the inserting an insulation layer into a pressure chamber of a diamond anvil cell comprises:
placing a T301 steel sheet into the pressure chamber and pre-pressing the T301 steel sheet by a thickness of 40 μm via the diamond anvil cell;
punching the pre-pressed T301 steel sheet using a laser boring device to obtain a sample chamber having a diameter of 300 μm; and
filling an insulation powder in the sample chamber, and pre-pressing the sample chamber filled with the insulation powder such that the insulation powder is attached to the T301 steel sheet.

11. The system of claim 9, wherein the pressure-calibrating substance includes ruby.

12. The system of claim 11, wherein a pressure is calibrated by a fluorescence peak of the ruby when the pressure chamber is pressurized by rotating a press bolt on the diamond anvil cell.

13. The system of claim 9, wherein the pressure chamber is pressurized by rotating a press bolt on the diamond anvil cell at pressure points of 1.0 GPa, 1.9 GPa, 2.5 GPa, 3.1 GPa, and 3.7 GPa.

14. The system of claim 13, further comprising a Keithley 2461 source meter and a pulse laser;
wherein, after the pressurizing the pressure chamber by rotating a press bolt on the diamond anvil cell, the method further comprises:
conducting an in situ high pressure photoresponse test on the BiOBr, comprising:
connecting one end of a wire to the electrode, and drawing the other end of the wire outside the diamond anvil cell and connecting to the Keithley 2461 source meter;
using the Keithley 2461 source meter as equipment for the in situ high pressure photoresponse test on the BiOBr, and using the Keithley 2461 source meter to apply a 10 V bias voltage to the BiOBr;
using the pulse laser with a frequency of 1 Hz as a light source to intermittently irradiate the BiOBr, wherein an irradiation time is 0.5 s, the same as an interval time; and
recording a current-time curve at each of the pressure points in a process of intermittent irradiation, determining whether a photo-responsivity and a photo-response speed of the BiOBr are enhanced according to the current-time curve, and determining a pressure applied for photoelectric detection of the BiOBr.

15. The system of claim 14, wherein the pulse laser irradiates the BiOBr at an optical power density of 0.3 mW/cm².

16. A method involving treatment of BiOBr material in a pressure chamber, the method comprising:
inserting an insulation layer into a pressure chamber of a diamond anvil cell and adding BiOBr, disposing two platinum sheets on the BiOBr as an electrode, and placing a pressure-calibrating substance on a culet of the diamond anvil cell;
pressurizing the pressure chamber by rotating a press bolt on the diamond anvil cell; and
treating the BiOBr under pressurization in the pressure chamber.

17. The method of claim 16, wherein the diamond anvil cell has a culet diameter of 400 μm.

18. The method of claim 16, wherein the inserting an insulation layer into a pressure chamber of a diamond anvil cell comprises:
placing a T301 steel sheet into the pressure chamber and pre-pressing the T301 steel sheet by a thickness of 40 μm via the diamond anvil cell;
punching the pre-pressed T301 steel sheet using a laser boring device to obtain a sample chamber having a diameter of 300 μm; and
filling an insulation powder in the sample chamber, and pre-pressing the sample chamber filled with the insulation powder such that the insulation powder is attached to the T301 steel sheet.

19. The method of claim 16, further comprising conducting an in situ high pressure photoresponse test on the BiOBr, including:
connecting one end of a wire to the electrode, and drawing the other end of the wire outside the diamond anvil cell and connecting to a Keithley 2461 source meter;
using the Keithley 2461 source meter as equipment for the in situ high pressure photoresponse test on the BiOBr, and using the Keithley 2461 source meter to apply a 10 V bias voltage to the BiOBr;
using a pulse laser with a frequency of 1 Hz as a light source to intermittently irradiate the BiOBr, wherein an irradiation time is 0.5 s, the same as an interval time; and
recording a current-time curve at each of the pressure points in a process of intermittent irradiation, determining whether a photo-responsivity and a photo-response speed of the BiOBr are enhanced according to the current-time curve, and determining a pressure applied for photoelectric detection of the BiOBr.

20. A BiOBr substrate produced by the method of claim 16, wherein the BiOBr substrate has one or more characteristics adjusted as a function of performing the method thereon, such as a photoelectric characteristic altered as a result of the pressure treatment (e.g., photo responsivity, photo-response speed, relative absorption intensity, band gap, etc.).

21. A BiOBr substrate produced by the method of claim 1, wherein the BiOBr substrate has one or more characteristics adjusted as a function of performing the method thereon, such as a photoelectric characteristic altered as a result of the pressure treatment (e.g., photo responsivity, photo-response speed, relative absorption intensity, band gap, etc.).
